(19) United States
(12) Patent Application Publication
(10) Pub. No.: US 2024/0224758 A1
(43) Pub. Date: Jul. 4, 2024

(54) LIGHT EMITTING DISPLAY DEVICE

(71) Applicant: LG Display Co., Ltd., Seoul (KR)

(72) Inventors: SeongYeong KIM, Busan (KR); SeYeoul KWON, Goyang-si (KR); ChangSoo KIM, Paju-si (KR); Cheolhwan LEE, Suwon-si (KR); JeongOk JO, Seoul (KR); Kwanghyun CHOI, Seoul (KR)

(21) Appl. No.: 18/538,984

(22) Filed: Dec. 13, 2023

(30) Foreign Application Priority Data
Dec. 30, 2022 (KR) 10-2022-0190610

(51) Int. Cl. H10K 59/80; H10K 59/126

(52) U.S. Cl. CPC H10K 59/879; H10K 59/126

(57) ABSTRACT

Provided is a light emitting display device. The light emitting display device includes a substrate in which a plurality of sub pixels is defined. The device includes an anode disposed on the substrate and disposed so as to correspond to each of the plurality of sub pixels. The device includes an emission layer disposed on the anode, a cathode disposed on the emission layer, a bank covering an edge of the anode to define an emission area, an encapsulation layer disposed on the cathode. The device also includes a light shielding pattern disposed on the encapsulation layer and enclosing a part of the emission area with respect to a plane. The device further includes a lens which is disposed on the light shielding pattern so as to correspond to the emission area and refracts light from the emission area.

### CROSS-REFERENCE TO RELATED APPLICATIONS

This application claims the priority of Korean Patent Application No. 10-2022-0190610 filed on Dec. 30, 2022, in the Korean Intellectual Property Office, the disclosure of which is incorporated herein by reference.

### BACKGROUND

### Technical Field

The present disclosure relates to a light emitting display device, and more particularly, to a light emitting display device with an improved luminous efficiency which has an asymmetric viewing angle.

### Description of the Related Art

An organic light emitting diode (OLED) which is a self-emitting device includes an anode electrode, a cathode electrode, and an organic compound layer formed therebetween. The organic compound layer is formed of a hole transport layer (HTL), an emission layer (EML), and an electron transport layer (ETL). When a driving voltage is applied to the anode electrode and the cathode electrode, holes which pass through the hole transport layer HTL and electrons which pass through the electron transport layer ETL move to the emission layer EML to form excitons so that the emission layer EML generates visible rays. An active matrix type light emitting display device includes an organic light emitting diode OLED which is a self-emitting device and is used in various ways with the advantages of a fast response speed, large emission efficiency, luminance, and viewing angle.

The light emitting display device disposes pixels each including an organic light emitting diode in a matrix and adjusts a luminance of the pixels in accordance with a gray scale level of video data.

### BRIEF SUMMARY

Various embodiments of the present disclosure provide a light emitting display device having an asymmetric viewing angle in which a viewing angle representing a maximum luminance is moved.

Various embodiments of the present disclosure provide a light emitting display device which restricts a part of a viewing angle.

Various embodiments of the present disclosure provide a light emitting display device which improves a luminance and reduces a power consumption at a specific viewing angle.

Technical benefits of the present disclosure are not limited to the above-mentioned benefits, and other benefits, which are not mentioned above, can be clearly understood by those skilled in the art from the following descriptions.

According to an aspect of the present disclosure, a light emitting display device includes a substrate in which a plurality of sub pixels is defined, each of the plurality of sub pixels including an emission area; a light-emitting diode; a light shielding pattern disposed on the light emitting diode and surrounding a part of an emission area of the light-emitting diode with respect to a plane; and a lens which is disposed on the light shielding pattern so as to correspond to the emission area and refracts light from the emission area.

According to another aspect of the present disclosure, a light emitting display device includes a substrate in which a plurality of sub pixels is defined; an anode disposed on the substrate and disposed so as to correspond to each of the plurality of sub pixels; an emission layer disposed on the anode; a cathode disposed on the emission layer; a bank covering an edge of the anode to define an emission area; an encapsulation layer disposed on the cathode; a light shielding pattern disposed on the encapsulation layer and enclosing a part of the emission area with respect to a plane; and a lens which is disposed on the light shielding pattern so as to correspond to the emission area and refracts light from the emission area.

Other detailed matters of the exemplary embodiments are included in the detailed description and the drawings.

According to the present disclosure, a half-cylindrical lens is used to restrict a viewing angle and improve an emission performance at a specific viewing angle.

According to the present disclosure, a light shielding pattern and a lens having a U-shape which is open in one direction are used to expand a viewing angle in one direction or move a viewing angle of a light emitting display device.

According to the present disclosure, a light emitting display device which restricts a part of a viewing angle to protect privacy and information and improves an emission performance of a main viewing angle of a user.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic plan view of a light emitting display device according to an exemplary embodiment of the present disclosure;

FIG. 2 is an enlarged plan view of one pixel of a light emitting display device according to an exemplary embodiment of the present disclosure;

FIG. 3 is a cross-sectional view taken along the line I-I′ of FIG. 2;

FIG. 4 is a cross-sectional view taken along the line II-II′ of FIG. 2;

FIG. 5 is a view schematically illustrating a lens of a light emitting display device according to an exemplary embodiment of the present disclosure;

FIG. 6 is an enlarged plan view of one pixel of a light emitting display device according to another exemplary embodiment of the present disclosure;

FIG. 7 is a cross-sectional view taken along the line III-III′ of FIG. 6; and

FIG. 8 is a graph illustrating a relative luminance for every viewing angle for display devices according to Exemplary Embodiments 1 and 2 and Comparative Embodiments 1 and 2.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, a light emitting display device according to exemplary embodiments of the present disclosure will be described in detail with reference to accompanying drawings.

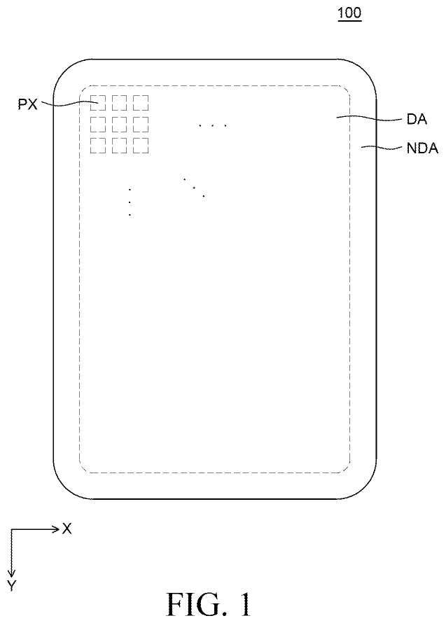

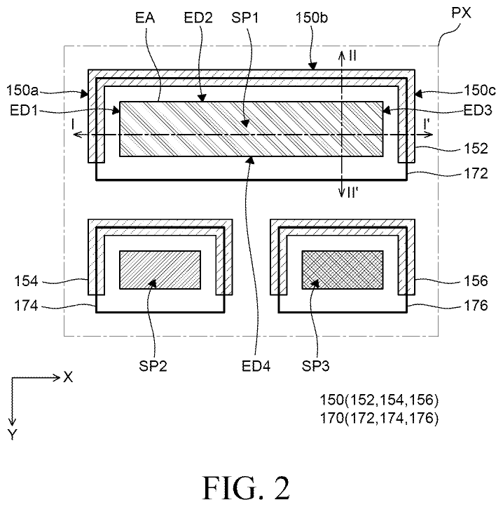

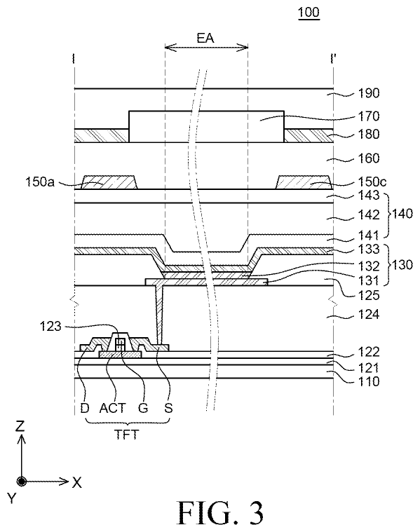

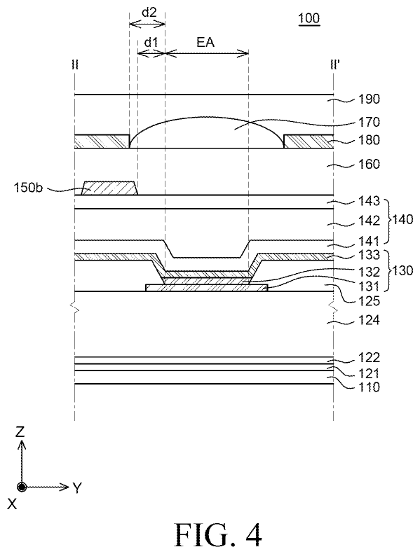

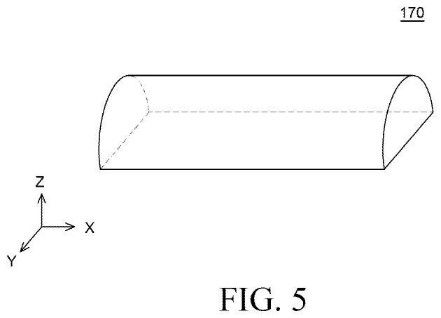

FIGS. 1 to 5 are views for explaining a light emitting display device according to an exemplary embodiment of the present disclosure. FIG. 1 is a schematic plan view of a light emitting display device according to an exemplary embodiment of the present disclosure. FIG. 2 is an enlarged plan view of one pixel of a light emitting display device according to an exemplary embodiment of the present disclosure. FIG. 3 is a cross-sectional view taken along the line I-I′ of FIG. 2. FIG. 4 is a cross-sectional view taken along the line II-II′ of FIG. 2. FIG. 5 is a view schematically illustrating a lens of a light emitting display device according to an exemplary embodiment of the present disclosure.

Referring to FIGS. 1 to 5, a light emitting display device 100 according to an exemplary embodiment of the present disclosure includes a substrate 110, a thin film transistor TFT, a light emitting diode 130, an encapsulation layer 140, a light shielding pattern 150, a lens layer 170, and a light shielding member 180.

Referring to FIG. 1, the light emitting display device 100 according to the exemplary embodiment of the present disclosure includes a display area DA and a non-display area NDA. The display area DA is an area where a plurality of pixels PX is disposed to substantially display images. In the display area DA, pixels PX including an emission area for displaying images and a driving circuit for driving the pixels PX may be disposed. The non-display area NDA encloses the display area DA. The non-display area NDA is an area where images are not substantially displayed and various wiring lines, driving ICs, printed circuit boards, and the like for driving the pixels disposed in the display area DA and the driving circuits are disposed. For example, in the non-display area NDA, various ICs such as a gate driver IC and a data driver IC may be disposed. In the meantime, as described above, in the non-display area NDA, the driving IC and the printed circuit board may be disposed and a selected (or in some cases, predetermined) area is beneficial to dispose the driving IC and the printed circuit board.

Each of the plurality of pixels PX may include a plurality of sub pixels. The sub pixel is an element for displaying one color and includes an emission area in which light is emitted and a non-emission area in which light is not emitted. In the present specification, an emission area in which light is emitted is defined as an area corresponding to an anode which is exposed by a bank in each sub pixel. That is, the emission area corresponds to an opening by the bank. Referring to FIG. 2, one pixel PX may include a first sub pixel SP1, a second sub pixel SP2, and a third sub pixel SP3. For example, the first sub pixel SP1 is disposed in the X-axis direction (or a second direction) and the second sub pixel SP2 and the third sub pixel SP3 are spaced apart from the first sub pixel SP1 in a Y-axis direction (or a first direction) to be alternately disposed in the X-axis direction (or the second direction).

The first sub pixel SP1, the second sub pixel SP2, and the third sub pixel SP3 may display different colors and some sub pixels may display the same color as needed. Specifically, each of the first sub pixel SP1, the second sub pixel SP2, and the third sub pixel SP3 may be any one of a red sub pixel, a green sub pixel, and a blue sub pixel. For example, the first sub pixel SP1 is a blue sub pixel, the second sub pixel SP2 is a red sub pixel, and the third sub pixel SP3 is a green sub pixel. At this time, the third sub pixel SP3 which is green and the second sub pixel SP2 which is red may have a smaller area than the first sub pixel SP1 which is blue, in consideration of the luminance and the color temperature. Hereinafter, the light emitting display device 100 according to the exemplary embodiment of the present disclosure will be described under the assumption that the first sub pixel SP1 is a blue sub pixel, the second sub pixel SP2 is a red sub pixel, and the third sub pixel SP3 is a green sub pixel. However, colors of the sub pixels are described as an example for the convenience of description so that the present disclosure is not limited thereto.

In FIG. 2, it is illustrated that the plurality of sub pixels SP1, SP2, and SP3 is formed with a pentile structure, but is not limited thereto. The color and the arrangement of the sub pixels may vary in various forms depending on the necessity. Further, in FIG. 2, it is illustrated that each of the plurality of sub pixels SP1, SP2, and SP3 has a quadrangular shape, but it is not limited thereto and the shape of the sub pixels may be changed to various shapes. For example, each sub pixel may have a polygonal shape such as an octagonal shape, a circular shape or an oval shape.

Furthermore, one pixel PX may also include a first sub pixel SP1, a second sub pixel SP2, a third sub pixel SP3, and a fourth sub pixel SP4. The first sub pixel SP1, the second sub pixel SP2, a third sub pixel SP3, and a fourth sub pixel SP4 may display different colors and some sub pixels may display the same color as needed. Specifically, each of the first sub pixel SP1, the second sub pixel SP2, a third sub pixel SP3, and a fourth sub pixel SP4 may be any one of a red sub pixel, a green sub pixel, a blue sub pixel and a white sub pixel.

Meanwhile, each of the plurality of sub pixels SP1, SP2, SP3 and SP4 has a quadrangular shape, but it is not limited thereto, and the shape of the sub pixels may be changed to various shapes. For example, each sub pixel may have a polygonal shape such as an octagonal shape, a circular shape, or an oval shape.

A structure of one sub pixel in a light emitting display device according to the exemplary embodiment of the present disclosure will be described with reference to FIGS. 3 and 4. FIGS. 3 and 4 are cross-sectional views taken along the lines I-I′ and II-II′ traversing the first sub pixel SP1 illustrated in FIG. 2 and a structure of one sub pixel will be described without distinguishing the first sub pixel SP1, the second sub pixel SP2, and the third sub pixel SP3.

Referring to FIGS. 3 and 4, the substrate 110 is a base material for supporting various components included in the light emitting display device 100 and may be formed of an insulating material. For example, the substrate 110 may be a glass substrate or a plastic substrate. For example, the plastic substrate may be selected from polyimide, polyethersulfone, polyethylene terephthalate, and polycarbonate, but is not limited thereto. In order to implement a flexibility and a foldability, when a plastic substrate having a flexibility is used, a support member such as a back plate may be disposed below the substrate 110. The plastic substrate having flexibility is relatively thinner and has a weaker rigidity than the glass substrate so that when various elements are disposed, the plastic substrate may be sagged. The back plate supports the substrate 110 formed of a plastic material so as not to be sagged and protects the light emitting display device 100 from moisture, heat, and impacts. For example, the back plate may be a metal material such as stainless steel (SUS) or a plastic material such as polymethylmethacrylate, polycarbonate, polyvinyl alcohol, acrylonitrile-butadiene-styrene, or polyethylene terephthalate.

A first buffer layer 121 may be disposed on the substrate 110 to suppress permeation of oxygen or moisture. The first buffer layer 121 is substantially located on the entire surface of the substrate 110. The first buffer layer 121 is formed of an inorganic material, such as silicon oxide SiO₂ or silicon nitride SiNx, and may be formed of a single layer or multiple layers. For example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

On the first buffer layer 121, a thin film transistor TFT including a gate electrode G, an active layer ACT, a source electrode S, and a drain electrode D is disposed. The thin film transistor TFT is disposed in each area of the first sub pixel SP1, the second sup pixel SP2, and the third sub pixel SP3, or is disposed in each area of the first sub pixel SP1, the second sup pixel SP2, the third sub pixel SP3, and the fourth sub pixel SP4. For example, the gate electrode G may be formed of a conductive material, for example, copper Cu, aluminum Al, molybdenum Mo, nickel Ni, titanium Ti, chromium Cr, or an alloy thereof, but not limited thereto. In FIG. 3, only a driving thin film transistor, among various thin film transistors which may be included in the light emitting display device 100, is illustrated for the convenience of description. Further, it is described that the thin film transistor TFT has a coplanar structure as an example in FIG. 3, but the present disclosure is not limited thereto and a thin film transistor TFT having an inverted staggered structure may also be used.

The thin-film transistor TFT may include any semiconductor layer of various types of semiconductor layers. For example, the semiconductor layer may be formed of one selected from among oxide semiconductor material, amorphous semiconductor material, or polycrystalline semiconductor material, but the present disclosure is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polysilicon, but is not limited thereto.

The amorphous semiconductor material may be made of amorphous silicon (Si), but is not limited thereto.

For example, the active layer ACT is disposed on the first buffer layer 121 and a gate insulating layer 123 is disposed on the active layer ACT to insulate the active layer ACT and the gate electrode G from each other. Further, an interlayer insulating layer 122 is disposed on the first buffer layer 121 to insulate the gate electrode G from the source electrode S and the drain electrode D. The source electrode S and the drain electrode D which are in contact with the active layer ACT, respectively, are formed on the interlayer insulating layer 122. The planarization layer 124 may be disposed on the thin film transistor TFT. The planarization layer 124 planarizes an upper portion of the thin film transistor TFT. The planarization layer 124 may include a contact hole which electrically connects the thin film transistor TFT and the anode 131 of the light emitting diode 130.

The light emitting diode 130 is disposed on the planarization layer 124. The light emitting diode 130 is disposed in each of the plurality of sub pixels SP1, SP2, and SP3. The light emitting diode 130 includes an anode 131, an emission layer 132, and a cathode 133.

The anode 131 is disposed on the planarization layer 124. The anode 131 is disposed so as to correspond to each of the plurality of sub pixels SP1, SP2, and SP3. The anode 131 is formed of a conductive material having a high work function to supply holes to the emission layer 132. The anode 131 may be a transparent conductive layer which is formed of transparent conductive oxide (TCO). For example, the anode 131 may be formed by one or more selected from transparent conductive oxides such as indium tin oxide (ITO), indium zinc oxide (IZO), indium tin zinc oxide (ITZO), tin oxide (SnO₂), zinc oxide (ZnO), indium copper oxide (ICO), and aluminum: zinc oxide (Al: ZnO, AZO), but is not limited thereto. When the light emitting display device 100 is driven as a top emission type, the anode 131 may further include a reflection layer which reflects light emitted from the emission layer 132 toward the cathode 133, for example, reflection layer may have a single-layer or multi-layer structure including Al, Ag, Cu, Pb, Mo, Ti or an alloy thereof. The anode 131 may be separately formed for each of the first sub pixel SP1, the second sub pixel SP2, and the third sub pixel SP3.

The bank 125 is disposed on the anode 131 and the planarization layer 124. The bank 125 may cover an edge of the anode 131 of the light emitting diode 130 to define an emission area. The bank 125 forms an opening on the anode 131 formed for each of the sub pixels SP1, SP2, and SP3 to define each emission area. Specifically, the bank 125 defines an emission area EA by forming an opening which exposes top surfaces of the anodes 131 of the sub pixels SP1, SP2, and SP3. For example, the bank 125 may be made of, for example, a transparent carbon-based mixture. Specifically, the bank BNK may contain carbon black, but is not limited thereto. The bank may also be made of a transparent insulating material.

The bank 125 may be formed of an insulating material which insulates anodes 131 of adjacent sub pixels SP1, SP2, and SP3 from each other. Further, the bank 125 may be configured by a black bank having high light absorptance to suppress color mixture between adjacent sub pixels SP1, SP2, and SP3. For example, the bank 125 may be formed of a polyimide resin, an acrylic resin, or a benzocyclobutene resin, but is not limited thereto. Alternatively, the bank 125 may include an inorganic insulating material such as silicon nitride, aluminum nitride, zirconium nitride, titanium nitride, hafnium nitride, tantalum nitride, silicon oxide, aluminum oxide, or titanium oxide, etc.

The cathode 133 is disposed on the anode 131. The cathode 133 may be formed of a metal material having a low work function to smoothly supply electrons to the emission layer 132. For example, the cathode 133 may be formed of a metal material selected from calcium (Ca), barium (Ba), aluminum (Al), silver (Ag), and alloys including one or more of them, but is not limited thereto. Referring to FIGS. 3 and 4, the cathode may be formed on the anode 131 as one layer. That is, the cathode 133 may be formed in the first sub pixel SP1, the second sub pixel SP2, and the third sub pixel SP3 as a single layer. When the light emitting display device 100 is driven as a top emission type, the cathode 133 may be formed to have a very small thickness to be substantially transparent.

The emission layer 132 is disposed between the anode 131 and the cathode 133. The emission layer 132 is disposed above the anode 131 exposed through an opening of the bank 125. The emission layer 132 may include a first charge auxiliary layer, a light emitting material layer, and a second charge auxiliary layer which are sequentially located from an upper portion of the anode 131. The light emitting material layer may be formed by any one of red, green, and blue light emitting materials, but is not limited thereto. However, the light emitting material may be an organic light emitting material such as a phosphorescent compound or a fluorescent compound. However, the present disclosure is not limited thereto and an inorganic light emitting material, such as a quantum dot may also be used. For example, an organic emission layer of the light emitting diode 130 of the first sub pixel SP1 may be a green emission layer. An organic emission layer of the light emitting diode 130 of the second sub pixel SP2 may be a red emission layer. An organic emission layer of the light emitting diode 130 of the third sub pixel SP3 may be a blue emission layer. The first charge auxiliary layer may include at least one of a hole injection layer HIL and a hole transport layer HTL. The second charge auxiliary layer may include at least one of an electron injection layer EIL and an electron transport layer ETL.

The encapsulation layer 140 is disposed on the light emitting diode 130. The encapsulating layer 140 may cover the light emitting diode 130. The encapsulation layer 140 may protect the light emitting diode 130 from moisture, oxygen, and impacts of the outside. The encapsulation layer 140 may be formed with a multilayered structure in which an inorganic layer formed of an inorganic insulating material and an organic layer formed of an organic material are laminated. For example, the encapsulation layer 140 may be configured by at least one organic layer and at least two inorganic layers and have a multilayered structure in which the inorganic layers and the organic layer are alternately laminated, but is not limited thereto. For example, the encapsulation layer 140 may have a triple-layered structure including a first inorganic layer 141, an organic layer 142, and a second inorganic layer 143. In this case, the first inorganic layer 141 and the second inorganic layer 143 may be independently formed of one or more selected from silicon nitride SiNx, silicon oxide SiOx, aluminum oxide AlOx, and silicon oxynitride SiON, but is not limited thereto. Further, the organic layer 142 may be formed of one or more selected from epoxy resin, polyimide, polyethylene, and silicon oxycarbide (SiOC), but is not limited thereto.

Meanwhile, the encapsulation layer 140 is not limited to three layers, for example, the encapsulation layer 140 may include n layers alternately laminated between inorganic encapsulation layer and organic encapsulation layer (where n is an integer greater than 3).

A light shielding pattern 150 is disposed above the encapsulation layer 140. The light shielding pattern 150 is formed to correspond between adjacent sub pixels SP1, SP2, and SP3 or is formed to correspond between emission areas of each sub pixel SP1, SP2, and SP3. The light shielding pattern 150 blocks light emitted from the light emitting diode at a specific angle. By doing this, the light shielding pattern 150 may restrict a viewing angle of each of the sub pixels SP1, SP2, and SP3 or move the viewing angle together with a lens layer to be described below. Such a light shielding pattern 150 may be a black matrix and may be formed of black resin, chrome oxide, or the like.

The light shielding pattern 150 includes a shielding area SA and an opening area OA. The shielding area blocks light from the inside or outside of the light emitting display device 100. The opening area transmits light from the inside or outside of the light emitting display device 100. The opening area may correspond to the emission area EA in which the light is emitted from the emission layer 132 of the light emitting diode 130. Referring to FIG. 2, a width of the opening area in the X-axis direction may be larger than a width of the emission area EA, but is not limited thereto. That is, the width of the opening area in the X-axis direction may be equal to a width of the emission area EA and the width of the opening area may be adjusted according to the viewing angle of the light emitting display device 100.

The light shielding pattern 150 has a shape partially enclosing the emission area EA with respect to an XY plane. At this time, the light shielding pattern 150 may have a shape which is downwardly open in one direction, for example, with respect to the Y-axis. The light shielding pattern 150 may move the viewing angle in one direction and/or expand a viewing angle for one direction by means of a shape open in one direction.

Hereinafter, a structure and a placement relationship of the emission area EA of the sub pixel and the light shielding pattern 150 will be described with reference to FIG. 2.

First, referring to FIG. 2, each of the plurality of sub pixels SP1, SP2, and SP3 includes an emission area EA defined by the bank 125. The emission area EA may have a quadrangular shape, but is not limited thereto so that the shape of the emission area EA may be changed in various forms. For example, each emission area EA may have a polygonal shape other than a circular shape, an oval shape, or an octagonal shape.

When the emission area EA has a quadrangular shape, the emission area EA includes a first edge ED1, a second edge ED2, a third edge ED3, and a fourth edge ED4 with respect to the XY plane. The first edge ED1 and the third edge ED3 extend in the Y-axis direction and are parallel to each other and the second edge ED2 and the fourth edge ED4 extend in the X-axis direction and are parallel to each other.

At this time, the light shielding pattern 150 includes a first light shielding unit 150a disposed to be parallel to the first edge ED1 of the emission area EA, a second light shielding unit 150b disposed to be parallel to the second edge ED2 of the emission area EA, and a third light shielding unit 150c disposed to be parallel to the third edge ED3 of the emission area EA. The first light shielding unit 150a, the second light shielding unit 150b, and the third light shielding unit 150c of the light shielding pattern 150 may have selected (or in some cases, predetermined) a width and a thickness and are connected to each other. By doing this, the light shielding pattern 150 is formed to enclose a part of the emission area EA along the first edge ED1, the second edge ED2, and the third edge ED3 of the emission area EA. At this time, the light shielding pattern 150 does not form a light shielding unit in an area corresponding to the fourth edge ED4 of the emission area EA. That is, the light shielding pattern 150 has a shape which is open in an area corresponding to the fourth edge ED4 of the emission area EA. Therefore, the light shielding pattern 150 has a shape which is open in a lower direction in the Y-axis direction (or a lower direction with respect to an XY plane) in which the fourth edge ED4 of the emission area EA is located. That is, the light shielding pattern 150 may have a “U” shape.

As illustrated in FIG. 2, the light shielding pattern 150 has a shape which is open only in one direction, for example, in a lower direction with respect to the Y-axis direction so that the viewing angle may be moved and/or expanded in the open direction. Referring to FIGS. 2 and 3 together, the light shielding pattern 150 blocks light emitted from the light emitting diode 130 at a specific angle in a left and right direction with respect to the X-axis direction, by a first light shielding unit 150a and a third light shielding unit 150c. Further, referring to FIGS. 2 and 4 together, the light shielding pattern 150 blocks light emitted from the light emitting diode 130 at a specific angle in an upper direction with respect to the Y-axis direction, by the second light shielding unit 150b. However, the light shielding pattern 150 does not include a light shielding unit in a lower direction with respect to the Y-axis direction so that the light shielding pattern does not block light emitted from the light emitting diode 130 at a specific angle in the lower direction with respect to the Y-axis direction. By doing this, the light shielding pattern 150 may move the viewing angle in one direction, that is, in the lower direction with respect to the Y-axis direction in which the light shielding pattern is open.

In the meantime, in FIG. 2, it is illustrated that the emission area EA has a quadrangular shape and correspondingly, the light shielding pattern 150 has a U-shaped structure which opens only in a portion corresponding to the fourth edge ED4 of the emission area EA and encloses the remaining edges ED1, ED2, and ED3. However, the light shielding pattern 150 is not limited to this structure and may vary in various forms corresponding to the shape of the emission area EA. For example, when the emission area EA has a circular shape, the light shielding pattern 150 may have a shape which is open in one direction and encloses a periphery of a circular emission area EA (for example, a horseshoe shape). Further, when the emission area EA has an octagonal shape, the light shielding pattern 150 may have a structure which has open parts corresponding to one to four edges, among eight edges of the emission area EA and encloses the periphery of the remaining edges.

In the meantime, the light shielding pattern 150 is spaced apart from the edge of the emission area EA with a selected (or in some cases, predetermined) interval d1. For example, the first light shielding unit 150a, the second light shielding unit 150b, and the third light shielding unit 150c of the light shielding pattern 150 are spaced apart from the first edge ED1, the second edge ED2, and the third edge ED3 of the emission area EA, respectively, with a selected (or in some cases, predetermined) interval. The interval between the light shielding pattern 150 and the edge of the emission area EA may be changed according to a desired viewing angle. Further, the light shielding pattern 150 may be spaced apart from the edge of the emission area EA with a selected (or in some cases, predetermined) interval, but may have partially different intervals. For example, in order to further restrict the viewing angle in the left and right direction with respect to the X-axis direction, the interval between the first light shielding unit 150a and the third light shielding unit 150c of the light shielding pattern 150 and the first edge ED1 and the third edge ED3 of the emission area EA may be smaller than the interval between the second light shielding unit 150b of the light shielding pattern 150 and the second edge ED2 of the emission area EA.

An optical gap layer 160 is provided above the light shielding pattern 150. The optical gap layer 160 ensures an optical gap between the light emitting diode 130 and lenses 172, 174, and 176 of the lens layer 170 to refract light from the light emitting diode 130 to a specific direction by the lenses 172, 174, and 176 to improve the efficiency of the lenses 172, 174, and 176. The optical gap layer 160 may have a thickness of several to several tens of μm and may be formed of an organic insulating material.

For example, the optical gap layer 160 may be formed of photo acryl, benzocyclobutene (BCB), polyimide (PI), or polyamide (PA), but is not limited thereto.

The lens layer 170 is provided above the optical gap layer 160. The lens layer 170 includes a first lens 172 corresponding to the first sub pixel SP1, a second lens 174 corresponding to the second sub pixel SP2, and a third lens 176 corresponding to the third sub pixel SP3. Each lens 172, 174, 176 is disposed on the emission area EA to refract light emitted from the light emitting diode 130 to a specific direction.

Each lens 172, 174, 176 refracts light emitted from the light emitting diode 130 at a specific angle to restrict the viewing angle. Specifically, each lens 172, 174, 176 may be a half-cylindrical lens. Accordingly, light emitted from the light emitting diode of each sub pixel is refracted at a specific angle by each lens to be output.

Specifically, as illustrated in FIG. 5, each lens 172, 174, 176 is a half-cylindrical lens and has a rectangle cross-section in the X-direction and a half-circular cross-section in the Y-axis direction. Accordingly, each lens 172, 174, 176 restricts a viewing angle in the Y-axis direction, but does not restrict the viewing angle in the X-axis direction. For example, when the half-cylindrical lens is provided, each sub pixel SP1, SP2, SP3 may have a narrow viewing angle which is 30 degrees or smaller in a up and down direction with respect to the Y-axis direction and have a wide viewing angle which is 60 degrees or larger in the left and right direction with respect to the X-axis direction.

Each lens 172, 174, 176 is disposed so as to overlap the emission area EA. An area of the lens may be larger than an area of the emission area EA, with respect to the XY plane. Further, each lens 172, 174, 176 is disposed so as to cover the entire emission area EA. Further, each lens 172, 174, 176 is disposed so as to overlap the light shielding pattern 150. Referring to FIGS. 2 and 3, when each lens 172, 174, 176 is a half-cylindrical lens, three edges, among four edges, of each lens 172, 174, 176 may overlap the first light shielding unit 150a, the second light shielding unit 150b, and the third light shielding unit 150c of the light shielding pattern 150 with respect to the XY plane.

The lens layer 170 may include a light shielding member 180 disposed between the lenses 172, 174, and 176. The light shielding member 180 absorbs or blocks light of the viewing angle to restrict the viewing angle together with the lenses 172, 174, and 176. The light shielding member 180 may be a black matrix and may be formed of black resin or chrome oxide, similar to the light shielding pattern 150. Further, the light shielding member 180 may be a touch electrode and may be formed of metal. At this time, the touch electrode may include a plurality of transmission electrodes and a plurality of reception electrodes intersecting each other and sense a touch from a variation of a capacitance between the plurality of transmission electrodes and the plurality of reception electrodes.

The light shielding member 180 may overlap the light shielding pattern 150 located therebelow. The light shielding member 180 may restrict the viewing angle or move the viewing angle, together with the light shielding pattern 150.

A planarization film 190 is provided above the lens layer 170 to protect each lens. The planarization film 190 is formed of an organic insulating material and has a flat top surface. A refractive index of the planarization film 190 is lower than a refractive index of each lens. For example, the planarization film 190 may be formed of photo acryl, benzocyclobutene (BCB), polyimide (PI), polyamide (PA), acrylic resin, epoxy resin, phenolic resin, unsaturated polyesters resin, polyphenylene resin, or polyphenylene sulfides resin, but is not limited thereto.

Even though it is not illustrated in the drawing, at least one or more of optical functional layers, such as a polarization layer may be disposed above the planarization film 190. The polarization layer serves to convert a polarized state of external light which is incident onto the light emitting display device 100 to suppress the external light from being reflected from the inside of the light emitting display device 100 and then emitted to the outside.

As mentioned above, generally, there is no restriction on a viewing angle of the light emitting display device, but recently, it is requested to limit the viewing angle for a reason, such as protection of privacy and information.

Further, various personal smart devices are being used so that usage of smart watches which include a light emitting display device to use various functions and applications is significantly increasing. The smart watch is located on a user's wrist so that the user looks downwardly with respect to the front of the smart watch. Accordingly, the viewing angle is frequently used in the downward direction of the smart watch and it is beneficial to restrict the viewing angle in an upward direction for the reason of privacy protection.

Accordingly, according to the type and an application field of the light emitting display device, a light emitting display device having an asymmetric viewing angle in which some viewing angles are restricted and the emission performance of other viewing angles is improved is demanded.

The light emitting display device according to the exemplary embodiment of the present disclosure forms a light shielding pattern which is open in a specific direction above the light emitting diode in each sub pixel and disposes a lens layer for restricting the viewing angle above the light shielding pattern. By doing this, a narrow viewing angle may be provided and the viewing angle may be moved in a specific direction or a viewing angle for the specific direction may be expanded. By doing this, depending on the location or the purpose of the light emitting display device, an asymmetric viewing angle is implemented and a luminous efficiency in a specific viewing angle may be increased or maximized.

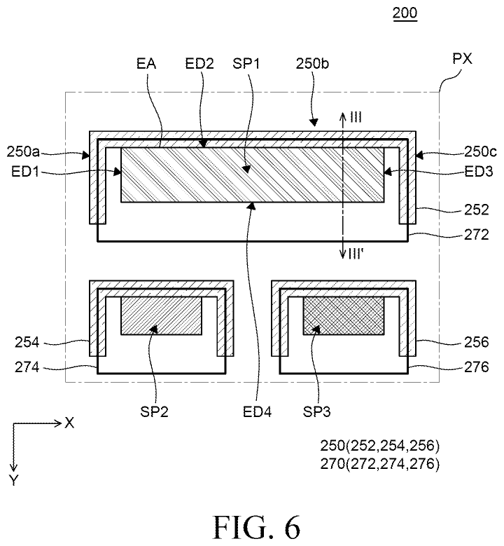

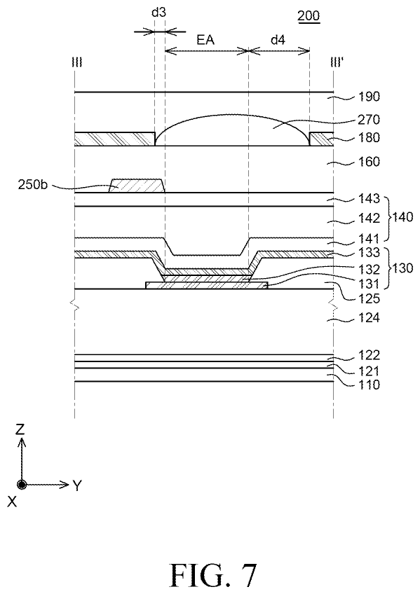

FIGS. 6 to 7 are views for explaining a light emitting display device according to another exemplary embodiment of the present disclosure. Specifically, FIG. 6 is an enlarged plan view of one pixel of a light emitting display device according to another exemplary embodiment of the present disclosure. FIG. 7 is a cross-sectional view taken along the line III-III′ of FIG. 6. A light emitting display device 200 illustrated in FIGS. 6 and 7 has the substantially same configurations as the light emitting display device 100 illustrated in FIGS. 1 to 5 except for the placement structure of a light shielding pattern 250 and a lens layer 270 so that a redundant description will be omitted.

Referring to FIGS. 6 and 7, the light shielding pattern 250 is disposed such that one side portion is adjacent to the emission area EA and the lenses 272, 274, and 276 are also disposed such that one side portions are adjacent to the emission area EA. As compared with the light shielding pattern 150 and the lenses 172, 174, and 176 illustrated in FIG. 2, the light shielding pattern 250 and the lenses 272, 274, and 276 illustrated in FIG. 6 move downwardly with respect to the Y-axis direction to be more adjacent to the emission area Ea.

Specifically, the second light shielding unit 150b of the light shielding pattern 150 is disposed to be in contact with the emission area EA. Referring to FIG. 7, one side portion of the second light shielding unit 250b of the light shielding pattern 250 may be disposed to be in complete contact with the emission area EA. That is, an interval between the second light shielding unit 250b of the light shielding pattern 250 and the second edge ED2 of the emission area EA is smaller than an interval between the first light shielding unit 250a of the light shielding pattern 250 and the first edge ED1 of the emission area EA and is smaller than an interval between the third light shielding unit 250c of the light shielding pattern 250 and the third edge ED3 of the emission area EA. That is, as compared with the light shielding pattern 150 illustrated in FIG. 2, the light shielding pattern 250 illustrated in FIG. 6 is disposed to move more in a direction for moving the viewing angle, that is, in a lower direction with respect to the Y-axis direction. This is a structure in which an open portion of the light shielding pattern 250 is disposed to move more in a direction for moving the viewing angle.

At this time, referring to FIG. 7, a first distance d3 between a first side surface of the emission area EA and a first side surface of lenses 272, 274, and 276 adjacent to the first side surface of the emission area EA is different from a second distance d4 between a second side surface which is an opposite side surface of the first side surface of the emission area EA and a second side surface of the lenses 272, 274, and 276 adjacent to the second side surface of the emission area. Specifically, as described above, as the light shielding pattern 250 is disposed to move downwardly with respect to the Y-axis direction, the lenses 272, 274, and 276 are also disposed such that one edge is closer to the emission area EA. That is, the first distance d3 is smaller than the second distance d4. As described above, edges of the lenses 272, 274, and 276 are disposed so as to overlap the light shielding pattern 250 so that as the light shielding pattern 250 is disposed to move downwardly with respect to the Y-axis direction, the lenses 272, 274, and 276 also are disposed to move downwardly with respect to the Y-axis direction. Therefore, the centers of the lenses 272, 274, and 276 may be located to be lower than the center of the emission area EA with respect to the Y-axis direction.

As compared with the light emitting display device illustrated in FIGS. 1 to 5, in FIGS. 6 and 7, the light shielding pattern and the lens are disposed to move downwardly with respect to the Y-axis direction. That is, the light shielding pattern and the lens are disposed to be more adjacent to the emission area in a viewing angle direction to move. With this structure, the viewing angle may further be moved.

Hereinafter, the effects of the present disclosure will be described in more detail with reference to Exemplary Embodiments. However, the following Exemplary Embodiments are set forth to illustrate the present disclosure, but the scope of the disclosure is not limited thereto.

### Exemplary Embodiment 1

As illustrated in FIGS. 2 to 4, a light shielding pattern 150 having a U-shape in which one direction was open and a lens layer 170 applied to manufacture a light emitting display device in which a viewing angle was moved. Specifically, the lens 172 is a half-cylindrical lens having a width of 15 μm and a height of 8 μm and a width of the emission area EA in the Y-axis direction is 8 μm. In a cross-sectional view, an interval d1 of one edge of the emission area EA and a second light shielding unit 150b of the light shielding pattern 150 is 2.2 μm, and in a cross-sectional view, an interval d2 of one edge of the emission area EA and the light shielding member 180 is 3.5 μm. Further, a thickness of the encapsulation layer 140 is 12 μm and a thickness of the optical gap layer 160 is 6 μm.

Exemplary Embodiment 1 is only one exemplary embodiment, each part of the present disclosure is not limited thereto. For example, the lens 172 may be a half-cylindrical lens having a width of 13 to 17 μm and a height of 7 to 9 μm and a width of the emission area EA in the Y-axis direction is 7 to 9 μm. In a cross-sectional view, an interval d1 of one edge of the emission area EA and a second light shielding unit 150b of the light shielding pattern 150 is 1.7 to 2.7 μm, and in a cross-sectional view, an interval d2 of one edge of the emission area EA and the light shielding member 180 is 2.5 to 4 μm. Further, a thickness of the encapsulation layer 140 is 10 to 14 μm and a thickness of the optical gap layer 160 is 5 to 7 μm.

### Exemplary Embodiment 2

As illustrated in FIGS. 5 and 6, as compared with a structure of Exemplary Embodiment 1, a light emitting display device in which the light shielding pattern 250 and the lens layer 270 were moved downwardly with respect to the Y-axis direction by 2.2 μm was manufactured. That is, a width of the emission area EA in the Y-axis direction is 8 μm. In a cross-sectional view, an interval d1 of one edge of the emission area EA and a second light shielding unit 150b of the light shielding pattern 250 is 0 μm, and in a cross-sectional view, an interval d2 of one edge of the emission area EA and the light shielding member 180 is 1.3 μm. Further, a thickness of the encapsulation layer 140 is 12 μm and a thickness of the optical gap layer 160 is 6 μm.

Exemplary Embodiment 2 is only one exemplary embodiment, each part of the present disclosure is not limited thereto. For example, the light shielding pattern 250 and the lens layer 270 may be moved downwardly with respect to the Y-axis direction by 1.7 to 2.7 μm was manufactured. A width of the emission area EA in the Y-axis direction is 7 to 9 μm. In a cross-sectional view, an interval d1 of one edge of the emission area EA and a second light shielding unit 150b of the light shielding pattern 250 is 0 μm, and in a cross-sectional view, an interval d2 of one edge of the emission area EA and the light shielding member 180 is 0.8 to 1.3 μm. Further, a thickness of the encapsulation layer 140 is 10 to 14 μm and a thickness of the optical gap layer 160 is 5 to 7 μm.

### Comparative Embodiment 1

A light emitting display device with the same structure as Exemplary Embodiment 1 was manufactured except that the light shielding pattern and the lens layer were not applied.

### Comparative Embodiment 2

A light emitting display device with the same structure as Exemplary Embodiment 1 was manufactured except that the light shielding pattern was not applied.

### Experimental Embodiment

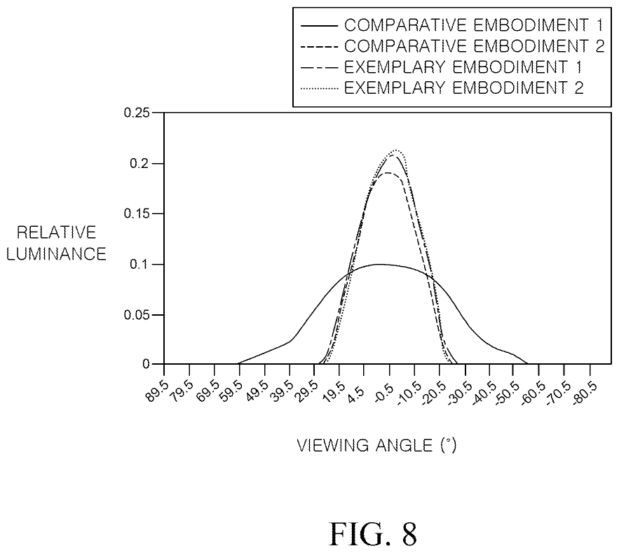

A relative luminance for every viewing angle for the light emitting display device of Exemplary Embodiments 1 and 2 and Comparative Embodiments 1 and 2 was measured. The result was represented in FIG. 8.

FIG. 8 is a graph illustrating a relative luminance for every viewing angle for display devices according to Exemplary Embodiments 1 and 2 and Comparative Embodiments 1 and 2.

Referring to FIG. 8, in Comparative Embodiment 1 in which the light shielding pattern and the lens were not provided, the viewing angle was not moved and the maximum luminance of 0.1 was obtained on a front surface. As compared with Comparative Embodiment 1, in Comparative Embodiment 2 which applied a lens, it was confirmed that the maximum luminance was greatly increased on the front surface and a narrow viewing angle of +30° in the vertical direction was provided. As compared with Comparative Embodiment 2, in Exemplary Embodiment 1 in which a light shielding pattern having a U-shape which was open in one direction was disposed between the light emitting diode and the lens, it was confirmed that the maximum luminance was increased to 0.2 or higher while moving the viewing angle downwardly by 5°. Further, in Exemplary Embodiment 2 in which the light shielding pattern and the lens were moved, it was confirmed that the maximum luminance was increased to 0.2 or higher while moving the viewing angle downwardly by 11°.

The exemplary embodiments of the present disclosure can also be described as follows:

According to an aspect of the present disclosure, there is provided a light emitting display device. The light emitting display device comprises a substrate in which a plurality of sub pixels is defined; an anode disposed on the substrate and disposed so as to correspond to each of the plurality of sub pixels; an emission layer disposed on the anode; a cathode disposed on the emission layer; a bank covering an edge of the anode to define an emission area; an encapsulation layer disposed on the cathode; a light shielding pattern disposed on the encapsulation layer and enclosing a part of the emission area with respect to a plane; and a lens which is disposed on the light shielding pattern so as to correspond to the emission area and refracts light from the emission area.

The light shielding pattern may have a shape which is open in a first direction with respect to the plane and enclose the other edges excluding one edge of the emission area corresponding to the first direction.

The light shielding pattern may have a U shape which is open in the first direction.

The light shielding pattern may be spaced apart from the emission area with a selected (or in some cases, predetermined) interval with respect to the plane.

The emission area may have a quadrangular shape with respect to the plane and the light shielding pattern have a shape enclosing the remaining edges excluding one edge.

The emission area may have a quadrangular shape with respect to the plane and the emission area may include a first edge and a third edge which extend in a first direction and are parallel to each other; and a second edge and a fourth edge which extend in a second direction perpendicular to the first direction and are parallel to each other. The light shielding pattern may include a first light shielding unit parallel to the first edge, a second light shielding unit parallel to the second edge, and a third light shielding unit parallel to the third edge.

The second light shielding unit may be connected to the first light shielding unit and the third light shielding unit and the light shielding pattern may have a shape in which a portion corresponding to the fourth edge of the emission area is open.

An interval between the second light shielding unit of the light shielding pattern and the second edge of the emission area may be smaller than an interval between the first light shielding unit of the light shielding pattern and the first edge of the emission area and be smaller than an interval between the third light shielding unit of the light shielding pattern and the third edge of the emission area.

The second light shielding unit of the light shielding pattern may overlap the second edge of the emission area.

A center of the lens with respect to the plane may be closer to the first direction than a center of the overlapping emission area.

A first distance between a first side surface of the emission area and a side surface of the lens adjacent to the first side surface of the emission area may be different from a second distance between a second side surface which is an opposite side surface of the first side surface of the emission area and a second side surface of the lens adjacent to the second side surface of the emission area.

The first side surface of the lens may overlap the first light shielding unit and the second side surface of the lens does not overlap the light shielding pattern.

The first distance may be shorter than the second distance.

The lens may be a half-cylindrical lens.

At least three edges of the lens may overlap the light shielding pattern with respect to the plane.

The light emitting display device may further comprise a light shielding member enclosing the lens.

The light shielding member may be a touch electrode.

The light emitting display device may further comprise an optical gap layer disposed between the light shielding pattern and the lens.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device, comprising:
a substrate,
a sub pixel on the substrate;
a light emitting diode within the sub pixel;
a light shielding pattern on the light emitting diode and enclosing a part of the emission area of the light emitting diode with respect to a plane; and
a lens which is on the light shielding pattern, the lens corresponding to the emission area, the lens refracting light from the emission area.

2. The light-emitting display device according to claim 1, wherein the light emitting diode comprising:
an anode disposed on the substrate and disposed so as to correspond to each of the plurality of sub pixels;
an emission layer disposed on the anode;
a cathode disposed on the emission layer;
an encapsulation layer disposed on the cathode;
wherein the light shielding pattern is disposed on the encapsulation layer.

3. The light-emitting display device according to claim 1, wherein the light shielding pattern has a shape partially surrounding edges of the emission area with respect to the plane.

4. The light emitting display device according to claim 1, wherein the light shielding pattern has a shape which is open in a first direction with respect to the plane and encloses the other edges excluding one edge of the emission area corresponding to the first direction.

5. The light emitting display device according to claim 4, wherein the light shielding pattern has a U shape which is open in the first direction.

6. The light emitting display device according to claim 5, wherein the light shielding pattern is spaced apart from the emission area with a selected interval with respect to the plane.

7. The light emitting display device according to claim 1, wherein the emission area has a quadrangular shape with respect to the plane and the light shielding pattern has a shape enclosing the remaining edges excluding one edge.

8. The light emitting display device according to claim 1, wherein the emission area has a quadrangular shape with respect to the plane and
wherein the emission area includes:
a first edge and a third edge which extend in a first direction and are parallel to each other; and
a second edge and a fourth edge which extend in a second direction perpendicular to the first direction and are parallel to each other, and
the light shielding pattern includes a first light shielding unit parallel to the first edge, a second light shielding unit parallel to the second edge, and a third light shielding unit parallel to the third edge.

9. The light emitting display device according to claim 8, wherein the second light shielding unit is coupled to the first light shielding unit and the third light shielding unit and the light shielding pattern has a shape in which a portion corresponding to the fourth edge of the emission area is open.

10. The light emitting display device according to claim 9, wherein an interval between the second light shielding unit of the light shielding pattern and the second edge of the emission area is smaller than an interval between the first light shielding unit of the light shielding pattern.

11. The light emitting display device according to claim 10, wherein the first edge of the emission area is smaller than an interval between the third light shielding unit of the light shielding pattern and the third edge of the emission area.

12. The light emitting display device according to claim 9, wherein the second light shielding unit of the light shielding pattern overlaps the second edge of the emission area.

13. The light emitting display device according to claim 11, wherein a center of the lens with respect to the plane is closer to the first direction than a center of the overlapping emission area.

14. The light emitting display device according to claim 8, wherein a first distance between a first side surface of the emission area and a side surface of the lens adjacent to the first side surface of the emission area is different from a second distance between a second side surface which is an opposite side surface of the first side surface of the emission area and a second side surface of the lens adjacent to the second side surface of the emission area.

15. The light emitting display device according to claim 14, wherein the first side surface of the lens overlaps the first light shielding unit and the second side surface of the lens does not overlap the light shielding pattern.

16. The light emitting display device according to claim 15, wherein the first distance is shorter than the second distance.

17. The light emitting display device according to claim 1, wherein the lens is a half-cylindrical lens.

18. The light emitting display device according to claim 17, wherein at least three edges of the lens overlap the light shielding pattern with respect to the plane.

19. The light emitting display device according to claim 1, further comprising:
a light shielding member enclosing the lens.

20. The light emitting display device according to claim 19, wherein the light shielding member is a touch electrode.

21. The light emitting display device according to claim 1, further comprising;
an optical gap layer between the light shielding pattern and the lens.
